(19) United States
(12) Patent Application Publication
(10) Pub. No.: US 2026/0309747 A1
(43) Pub. Date: Oct. 8, 2026

(54) FIXTURE DEVICE, TESTING SYSTEM, AND POSITIONING ROD FOR INTEGRATED CIRCUIT SUBSTRATE TESTING

(71) Applicant: MPI CORPORATION, CHU-PEI CITY (TW)

(72) Inventors: YA-HUNG LO, CHU-PEI CITY (TW); SHOU-JEN TSAI, CHU-PEI CITY (TW); FUH-CHYUN TANG, CHU-PEI CITY (TW)

(73) Assignee: MPI CORPORATION, CHU-PEI CITY (TW)

(21) Appl. No.: 19/375,828

(22) Filed: Oct. 31, 2025

Related U.S. Application Data
(60) Provisional application No. 63/714,900, filed on Nov. 1, 2024.

(30) Foreign Application Priority Data
Sep. 12, 2025 (TW) 114135205

(51) Int. Cl. G01R 1/04

(52) U.S. Cl. CPC G01R 1/0466

(57) ABSTRACT

A fixture device for IC substrate testing includes a base defining length, width and height axes, and two positioning rods disposed on the base to extend along the length axis, and each formed downward from their top surface's edge with a main step including clamping and supporting surfaces, wherein at least one positioning rod is slidable on the base along the width axis to adapt to a substrate's width, and fixable to the base so that the substrate is clamped by the two positioning rods. The clamping surfaces of the two positioning rods, at least one of which is formed from resilient material, face each other, and clamp the substrate, making its lower surface's non-tested contact region on the supporting surfaces, and tested contact region have a gap from the base. This invention meets testing requirements of substrates of various sizes and multiple substrates, having high testing flexibility.

### BACKGROUND OF THE INVENTION

### 1. Field of the Invention

The present invention relates to integrated circuit (also referred to as IC) substrate testing and more particularly, to a fixture device, a testing system, and a positioning rod for integrated circuit substrate testing.

### 2. Description of the Related Art

An IC substrate is a critical component in the packaging process. Its primary function is to serve as a carrier for carrying the IC, and being mounted on a printed circuit board (also referred to as PCB). Moreover, the internal circuit lines of the IC substrate are electrically connected between the IC and the PCB for transmitting signals between the IC and the PCB. Additionally, the IC substrate has the functions of circuit protection, securing the circuit lines, and dissipating excess heat.

Before an IC is mounted on the IC substrate, the IC substrate has to be tested to verify the quality of the internal circuit lines of the IC substrate. Therefore, how to secure the IC substrate, particularly how to secure IC substrates of various sizes or secure multiple IC substrates at the same time, for facilitating transportation and testing to enhance testing flexibility, has become an issue urgently in need of resolution in the industry.

### SUMMARY OF THE INVENTION

In view of the above-described prior art, an aspect of the present invention is to provide a fixture device for integrated circuit substrate testing, which is adapted for securing IC substrates of various sizes and/or multiple IC substrates, thereby enhancing testing flexibility.

Accordingly, in an aspect of the present invention, a fixture device for integrated circuit substrate testing is provided, which is adapted to clamp a substrate. The substrate includes an upper surface, and a lower surface. The lower surface includes a tested contact region, and a non-tested contact region. The fixture device includes a base, and two positioning rods. The base is defined with a length axis, a width axis, and a height axis, which are perpendicular to each other. Each positioning rod is disposed on the base so as to extend along the length axis. At least one of the two positioning rods is a slidable positioning rod. The slidable positioning rod is changeable between a slidable state and a fixed state. The slidable positioning rod in the slidable state is slidable relative to the base along the width axis for adapting to the width of the substrate. The slidable positioning rod in the fixed state is fixed to the base so that the substrate is fixedly clamped by the two positioning rods. Each positioning rod includes a top surface and a bottom surface, which face toward two opposite directions of the height axis respectively, and a main step formed downward into a step shape from an edge of the top surface. The main step includes a clamping surface adjacent to the top surface, and a supporting surface adjacent to the clamping surface. The clamping surfaces of the main steps of the two positioning rods face each other, and at least one of them is formed from an resilient material, such that the two positioning rods are arranged in a way that the clamping surfaces of the main steps of the two positioning rods are adapted to cooperatively clamp the substrate, the supporting surfaces of the main steps of the two positioning rods are adapted to cooperatively support the non-tested contact region of the lower surface of the substrate, and the two positioning rods are provided therebetween with a gap extending along the length axis and located between the tested contact region of the lower surface of the substrate and the base.

As a result, the two positioning rods may be both slidable positioning rods, or only one of them is the slidable positioning rod, but the other one is fixed to the base and non-slidable. By allowing the slidable positioning rod, in its slidable state, to slide relative to the base along the width axis, the relative positions of the two positioning rods can be adjusted. This adjustment changes the distance between the clamping surfaces of the main steps of the two positioning rods to adapt to the width of the substrate to be clamped. Once the adjustment is completed, the slidable positioning rod is capable of being changed to the fixed state so that the position of the slidable positioning rod is fixed, and the substrate is securely fixed on the fixture device for subsequent testing. In other words, the fixture device of the present invention can clamp substrates of different sizes by adjusting the distance between the two positioning rods. Moreover, multiple substrates of the same size can be arranged in a row along the length direction on the main steps of the two positioning rods without electrical interference. Even when the substrates of the same size have manufacturing tolerances, the clamping surface formed from the resilient material can absorb the dimensional tolerances of the substrates, allowing the multiple substrates with slight dimensional differences due to manufacturing tolerances to be all securely clamped by the two positioning rods. In addition, both the upper surface and the lower surface of the substrate include electrical contacts. During the substrate being tested, a probe for testing contacts the electrical contacts on the upper surface and presses on the substrate. At this time, the supporting surfaces of the main steps of the two positioning rods support the substrate at the non-tested contact region of the lower surface, and there is the gap between the tested contact region of the lower surface of the substrate and the base. Therefore, the electrical contacts on the lower surface of the substrate do not come into contact with the fixture device or the base, thereby prevented from electrical interference. Furthermore, the supporting surfaces of the main steps of the two positioning rods provide an appropriate force to support the substrate so that the substrate does not become detached from the fixture device.

Preferably, each positioning rod further includes a secondary step formed downward into a step shape from the supporting surface of the main step. The secondary step includes a receiving surface facing upward. On the height axis, the supporting surface of the main step is located between the top surface of the positioning rod and the receiving surface of the secondary step, the receiving surface of the secondary step is located between the supporting surface of the main step and the bottom surface of the positioning rod, the top surface of the positioning rod and the supporting surface of the main step are defined therebetween with a first height, the supporting surface of the main step and the receiving surface of the secondary step are defined therebetween with a second height, and the receiving surface of the secondary step and the bottom surface of the positioning rod are defined therebetween with a third height. The third height is larger than or equal to twice the sum of the first height and the second height.

As a result, since the supporting surface of the main step can contact only the non-tested contact region of the lower surface of the substrate, the supporting surface of the main step may have a very small width, such that the substrate may accidentally fall from the supporting surface of the main step. At this time, the receiving surface of the secondary step will receive the substrate, thereby preventing the substrate from falling onto the base. Moreover, due to the dimensional design that the third height is larger than or equal to twice the sum of the first and second heights, the height position of the receiving surface of the secondary step is very close to that of the supporting surface of the main step. Therefore, the falling height of the substrate from the supporting surface of the main step to the receiving surface of the secondary step is very small. Consequently, when a testing operator places the substrate back onto the supporting surface of the main step, the placement height is also very small. This reduces the risk that during the placement process, an adjacent substrate might be touched, and thereby the adjacent substrate might fall off as well.

More preferably, on the width axis, the main step has a first width, and the secondary step has a second width. The second width is larger than or equal to three times the first width.

As a result, the secondary step can effectively receive the substrate that falls from the main step, and prevent the substrate from further falling from the secondary step.

More preferably, the first height is smaller than or equal to the thickness of the substrate.

During the substrate being tested, the probe for testing and the fixture device are moved relative to each other on the height axis so as to approach each other to make the probe tip of the probe contact the electrical contact on the upper surface of the substrate. However, if the probe firstly contacts the positioning rod, interference will occur, disabling the probe tip of the probe from contacting the electrical contact on the upper surface of the substrate, thereby hindering proper testing and causing damage to the probe. The dimensional design that the first height is smaller than or equal to the thickness of the substrate ensures that the upper surface of the substrate is not lower than the top surface of the positioning rod. This can effectively avoid the aforementioned interference between the probe and the positioning rod.

Preferably, the base includes a main body, and two width-axial guiding members. The two width-axial guiding members are spaced from each other for a distance, and disposed on the main body so as to extend along the width axis. The slidable positioning rod includes a first end portion, and a second end portion. The first end portion and the second end portion are disposed on the two width-axial guiding members respectively. In the slidable state, the slidable positioning rod slides along the width axis by being guided by the two width-axial guiding members.

As a result, the two width-axial guiding members can guide the slidable positioning rod to slide along the width axis, facilitating the adjustment of the position of the slidable positioning rod.

More preferably, each width-axial guiding member includes a guiding groove extending along the width axis. The guiding groove includes a guiding portion, and an accommodating portion. Each of the first end portion and the second end portion of the slidable positioning rod has a through hole. Each of the first end portion and the second end portion is provided with a bolt inserted through the through hole, and a nut screwed onto the bolt. The bolt is inserted through the guiding portion of the guiding groove. The nut is disposed in the accommodating portion of the guiding groove, and able to be screwed tightly on the bolt to fasten the slidable positioning rod to the width-axial guiding member.

As a result, by the user simply loosening the bolts of the first and second end portions of the slidable positioning rod, the slidable positioning rod can be placed in the slidable state, and the bolts can be guided by the guiding portions of the guiding grooves. Thereafter, the user only needs to tighten the bolts to place the slidable positioning rod in the fixed state. The operation is quite fast and convenient.

Preferably, when the substrate is fixedly clamped by the two positioning rods, the upper surface of the substrate is flush with or higher than the top surfaces of the two positioning rods.

As a result, when the probe for testing and the fixture device are moved relative to each other along the height axis to approach each another, the probe will not firstly contact the positioning rod. Therefore, interference between the probe and the positioning rod is effectively prevented, allowing the testing to proceed well and avoiding damage to the probe.

Preferably, each positioning rod includes a first end portion, a second end portion, and a stopping portion connected with the first end portion for the substrate to be stopped by the stopping portions of the two positioning rods. The fixture device further includes a length-axial positioning member disposed between the two positioning rods. The length-axial positioning member is adjustable in position along the length axis for contacting the substrate between the first end portions and the second end portions of the two positioning rods.

As a result, in addition to clamping the substrate on the width axis by the clamping surfaces of the main steps of the two positioning rods, the fixture device of the present invention can further clamp a single substrate or multiple substrates arranged in a row along the length axis by the stopping portions of the two positioning rods and the length-axial positioning member on the length axis. That makes the substrate fixed to the fixture device more securely, and prevents the substrate from moving along the length axis.

More preferably, the fixture device further includes a length-axial guiding member disposed between the two positioning rods. The length-axial guiding member includes a guiding groove extending along the length axis. The guiding groove includes a guiding portion, and an accommodating portion. The length-axial positioning member includes a bolt, and a nut screwed onto the bolt. The bolt is inserted through the guiding portion of the guiding groove. The nut is disposed in the accommodating portion of the guiding groove, and able to be screwed tightly on the bolt, thereby fastened to the length-axial guiding member.

As a result, by the user simply loosening the bolt of the length-axial positioning member, the length-axial positioning member can slide along the guiding groove, so that the length-axial positioning member can be moved to a position where it contacts the substrate. Thereafter, the bolt is tightened to fix the position of the length-axial positioning member. The operation is quite fast and convenient.

Preferably, at least one of the two positioning rods further includes another aforementioned main step formed downward into a step shape from another edge of the top surface. At least one of the clamping surfaces of the two main steps included in the same positioning rod is formed from the aforementioned resilient material.

As a result, the positioning rod including two main steps can cooperate with positioning rods arranged on two sides thereof to clamp substrates. In other words, the fixture device of the present invention may include more than two positioning rods, and every two adjacent positioning rods can be used to clamp the substrate of a size. In other words, as long as the fixture device of the present invention is equipped with more than two positioning rods, it can clamp substrates of different sizes at the same time. As long as one of the two clamping surfaces cooperatively clamping a same substrate is formed from the resilient material, the effect of absorbing the manufacturing tolerances of the substrates can be achieved. Therefore, for the clamping surfaces of the two main steps included in the same positioning rod, only at least one of them is desired being formed from the resilient material.

In another aspect of the present invention, a testing system for integrated circuit substrate testing is provided, which is adapted for testing a substrate. The testing system includes a chuck, a fixture device as described above, and a probe device. The fixture device is disposed on the chuck for clamping the substrate. The probe device includes a probe seat, and a probe disposed on the probe seat for testing the substrate clamped on the fixture device.

As a result, the testing system of the present invention is equipped with the above-described fixture device, thereby having the advantages and effects thereof. It can meet the testing requirements for IC substrates of various sizes and multiple IC substrates, thereby enhancing the testing flexibility.

Preferably, each positioning rod of the fixture device further includes a secondary step formed downward into a step shape from the supporting surface of the main step. The secondary step includes a receiving surface facing upward. On the height axis, the supporting surface of the main step is located between the top surface of the positioning rod and the receiving surface of the secondary step. For each positioning rod, the height defined between the top surface thereof and the supporting surface of the main step thereof along the height axis is smaller than or equal to the thickness of the substrate.

As a result, if the substrate accidentally falls from the supporting surface of the main step, the receiving surface of the secondary step will receive the substrate and prevent it from falling onto the base. At this time, the testing operator can more easily place the substrate back onto the supporting surface of the main step. In addition, during the substrate being tested, the chuck and the probe device are moved relative to each other along the height axis to approach each another to make the probe tip of the probe contact the electrical contact on the upper surface of the substrate clamped by the fixture device on the chuck. However, if the probe firstly contacts the positioning rod, interference will occur, disabling the probe tip of the probe from contacting the electrical contact on the upper surface of the substrate, thereby hindering proper testing and causing damage to the probe. The dimensional design that the height between the top surface of the positioning rod and the supporting surface of the main step is smaller than or equal to the thickness of the substrate ensures that the upper surface of the substrate is not lower than the top surface of the positioning rod. This can effectively prevent the aforementioned interference between the probe and the positioning rod.

Preferably, the probe tip of the probe and the bottom surface of the probe seat are defined therebetween with a vertical distance along the height axis. For each positioning rod, the height defined between the top surface thereof and the supporting surface of the main step thereof along the height axis is smaller than half the vertical distance.

This can prevent the probe from collision with the fixture device or the substrate during testing the substrate, so as to avoid damage to the probe or the substrate that may be resulted from such collision.

In still another aspect of the present invention, a positioning rod of a fixture device for integrated circuit substrate testing is provided, which is defined with a length axis, a width axis, and a height axis, which are perpendicular to each other. The positioning rod extends into an elongated shape along the length axis. The positioning rod includes a top surface and a bottom surface, which face toward two opposite directions of the height axis respectively, and two main steps formed downward into a step shape from two opposite edges of the top surface respectively. Each main step includes a clamping surface adjacent to the top surface, and a supporting surface adjacent to the clamping surface. The clamping surface of each main step is adapted to cooperate with another positioning rod to clamp a substrate. At least one of the clamping surfaces of the two main steps is formed from a resilient material.

As a result, the positioning rod is applicable to the above-described fixture device. Two sides of the positioning rod can each cooperate with another positioning rod to clamp one substrate or multiple substrates arranged in a row along the length direction. That is, a same positioning rod can be used to clamp substrates of the same or different sizes. In this way, the space of the fixture device for placement of a batch of substrates for testing can be expanded, so that the fixture device has relatively higher usage flexibility. Secondly, as long as the clamping surface of one of the two positioning rods cooperatively clamping a same substrate is formed from the resilient material, the effect of absorbing the manufacturing tolerances of the substrates can be achieved. Therefore, for the clamping surfaces of the two main steps included in the positioning rod, only at least one of them is desired being formed from the resilient material.

Preferably, the positioning rod further includes two secondary steps formed downward into a step shape from the supporting surfaces of the two main steps respectively. Each secondary step includes a receiving surface facing upward. On the height axis, the supporting surface of each main step is located between the top surface of the positioning rod and the receiving surface of each secondary step, the receiving surface of each secondary step is located between the supporting surface of each main step and the bottom surface of the positioning rod, the top surface of the positioning rod and the supporting surface of each main step are defined therebetween with a first height, the supporting surface of each main step and the receiving surface of each secondary step are defined therebetween with a second height, and the receiving surface of each secondary step and the bottom surface of the positioning rod are defined therebetween with a third height. The third height is larger than or equal to twice the sum of the first height and the second height.

As a result, since the supporting surface of the main step is configured to support the substrate at the non-tested contact region of the lower surface, the supporting surface of the main step may have a very small width. If the substrate accidentally falls from the supporting surface of the main step, the receiving surface of the secondary step will receive the substrate. At this time, the testing operator can more easily place the substrate back onto the supporting surface of the main step. Moreover, due to the dimensional design that the third height is larger than or equal to twice the sum of the first and second heights, the height position of the receiving surface of the secondary step is very close to that of the supporting surface of the main step. Therefore, the falling height of the substrate from the supporting surface of the main step to the receiving surface of the secondary step is very small. Consequently, when the testing operator places the substrate back onto the supporting surface of the main step, the placement height is also very small. This reduces the risk that during the placement process, an adjacent substrate might be touched, and thereby the adjacent substrate might fall off as well.

More preferably, on the width axis, each main step has a first width, and each secondary step has a second width. The second width is larger than or equal to three times the first width.

As a result, the secondary step can effectively receive the substrate that falls from the main step, and prevent the substrate from further falling from the secondary step.

More preferably, the first height is smaller than or equal to the thickness of the substrate.

As a result, during the substrate being tested, the probe for testing is moved relative to the positioning rod and the substrate on the height axis so as to approach each other to make the probe tip of the probe contact the electrical contact on the upper surface of the substrate. However, if the probe firstly contacts the positioning rod, interference will occur, disabling the probe tip of the probe from contacting the electrical contact on the upper surface of the substrate, thereby hindering proper testing and causing damage to the probe. The dimensional design that the first height is smaller than or equal to the thickness of the substrate ensures that the upper surface of the substrate is not lower than the top surface of the positioning rod. This can effectively prevent the aforementioned interference between the probe and the positioning rod.

The detailed structures, features, assembly or usage of the fixture device, the testing system and the positioning rod for integrated circuit substrate testing provided by the present invention will be described in the following detailed description of embodiments. However, those skilled in the field of the present invention should understand that the detailed descriptions and specific embodiments instanced for implementing the present invention are given by way of illustration only, not intended to limit the scope of the claims of the present invention.

### BRIEF DESCRIPTION OF THE DRAWINGS

FIG. 1 is a schematic perspective view of a testing system for integrated circuit substrate testing provided by a first preferred embodiment of the present invention, and multiple substrates.

FIG. 2 is a schematic front view of a part of FIG. 1.

FIG. 3 is a schematic bottom view of a substrate.

FIG. 4 is an assembled perspective view of a fixture device of the testing system.

FIG. 5 is an exploded perspective view of the fixture device.

FIG. 6 is an assembled perspective view of the fixture device and the substrate.

FIG. 7 is an exploded perspective view of a base of the fixture device.

FIG. 8 is an enlarged view of a part of the base.

FIG. 9 is a partial sectional view taken along the line 9-9 in FIG. 6, showing positioning rods of the fixture device are in a fixed state.

FIG. 10 is similar to FIG. 9, but showing that the positioning rods are in a slidable state.

FIG. 11 is an assembled perspective view of a positioning rod of the fixture device.

FIG. 12 is a sectional view of the positioning rod shown in FIG. 11.

FIG. 13 and FIG. 14 are assembled perspective views of another positioning rod of the fixture device.

FIG. 15 is a sectional view of the positioning rod shown in FIG. 13 and FIG. 14.

FIG. 16 is a sectional view taken along the line 16-16 in FIG. 6.

FIG. 17 is an assembled perspective view of still another positioning rod of the fixture device.

FIG. 18 is a sectional view of the positioning rod shown in FIG. 17.

FIG. 19 is a schematic top view of a part of a fixture device for integrated circuit substrate testing provided by a second preferred embodiment of the present invention, and multiple substrates.

FIG. 20 is a schematic sectional view taken long the line 20-20 in FIG. 19.

### DETAILED DESCRIPTION OF THE INVENTION

First of all, it is to be mentioned that same reference numerals used in the following embodiments and the appendix drawings designate same or similar elements or the structural features thereof. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

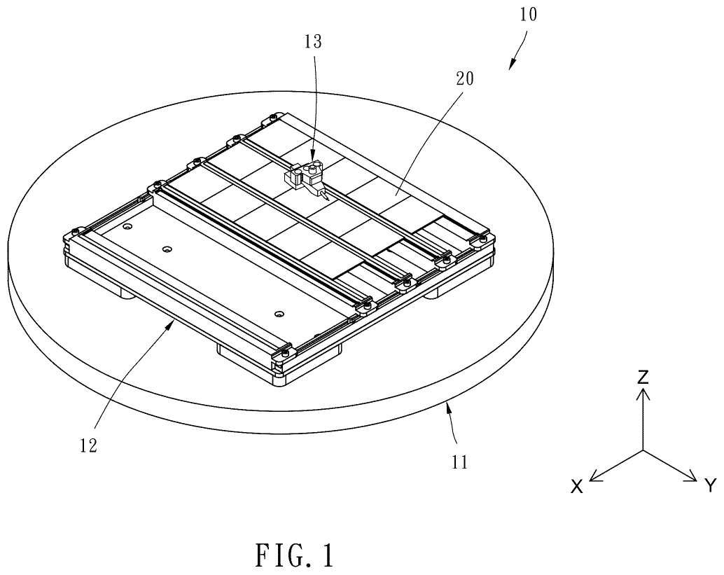

Referring to FIG. 1, a first preferred embodiment of the present invention provides a testing system 10 for integrated circuit substrate testing, which includes a chuck 11, a fixture device 12, and a probe device 13. The fixture device 12 is detachably fastened on the chuck 11. Its fastened manner is less related to the technical features of the present invention, thereby not described in detail herein and not shown in the figures, and the chuck 11 is only schematically represented by a circular plate. The fixture device 12 is adapted to clamp multiple substrates 20 (described in detail hereinafter), allowing the substrates 20 to be tested on the chuck 11. The substrate 20 mentioned in the present invention is an integrated circuit substrate, i.e. IC substrate.

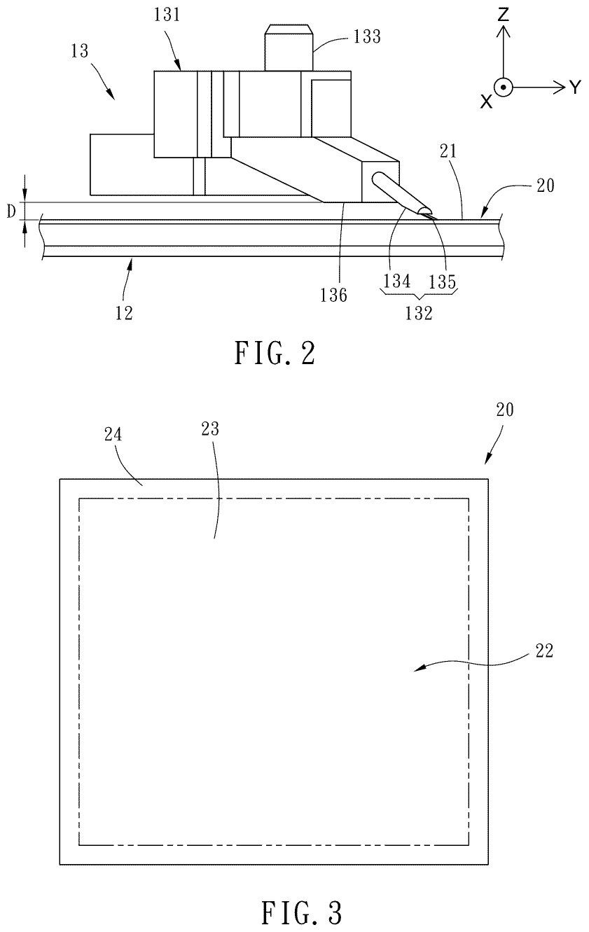

Referring to FIG. 2, the probe device 13 includes a probe seat 131, and a probe 132 and a connector 133 disposed on probe seat 131. The probe 132 in this embodiment is a high-frequency probe, which includes a probe body 134, and at least one probe tip 135 connected to the terminal end of the probe body 134. The probe body 134 is made of a coaxial copper tube having a coaxial cable structure, including a copper wire core, an insulating layer, and an outer conductor layer (not shown), which are coaxially arranged from the inside outward. Each probe tip 135 is a conductive piece. Typically, there may be two to five conductive pieces, which are electrically connected to the copper wire core and the outer conductor of the probe body 134 respectively. For example, two conductive pieces form a signal probe tip and a ground probe tip for contacting a signal electrical contact and a ground electrical contact of the IC substrate. The connector 133 is configured for connection with a cable (not shown) so that the probe 132 is electrically connected to a testing machine (not shown) through the cable.

At least one of the chuck 11 and the probe device 13 is moved by a movement device (not shown). For example, the chuck 11 is moved by a movement device (not shown) along Z-axis, and the probe device 13 is moved by another movement device (not shown) along X-axis and Y-axis, making the probe tip 135 of the probe 132 contact an electrical contact (not shown) on the upper surface 21 of the substrate 20, such that the substrate 20 can be electrically connected with the testing machine for testing. Referring to FIG. 3, the lower surface 22 of the substrate 20 is also provided with electrical contacts (not shown), and can be divided into a tested contact region 23 with the electrical contacts, and a non-tested contact region 24 without any electrical contact.

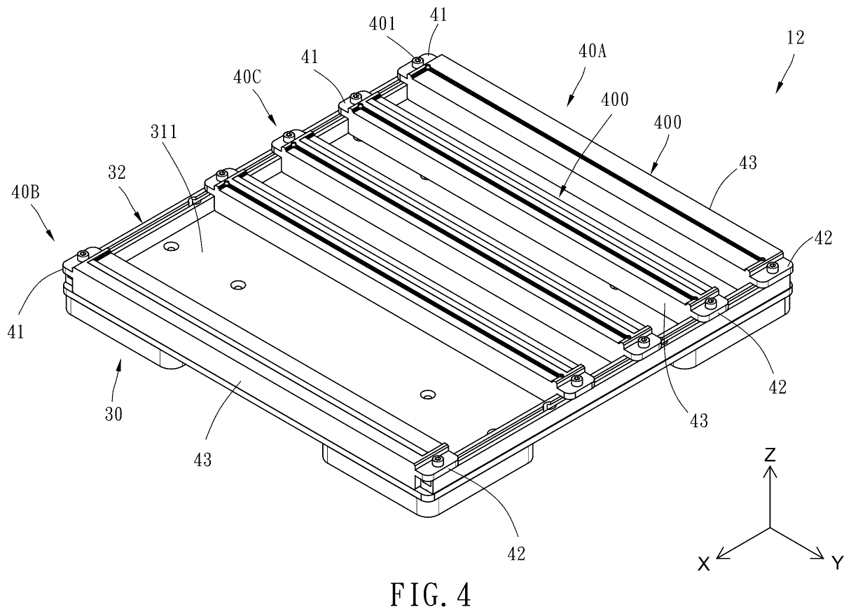

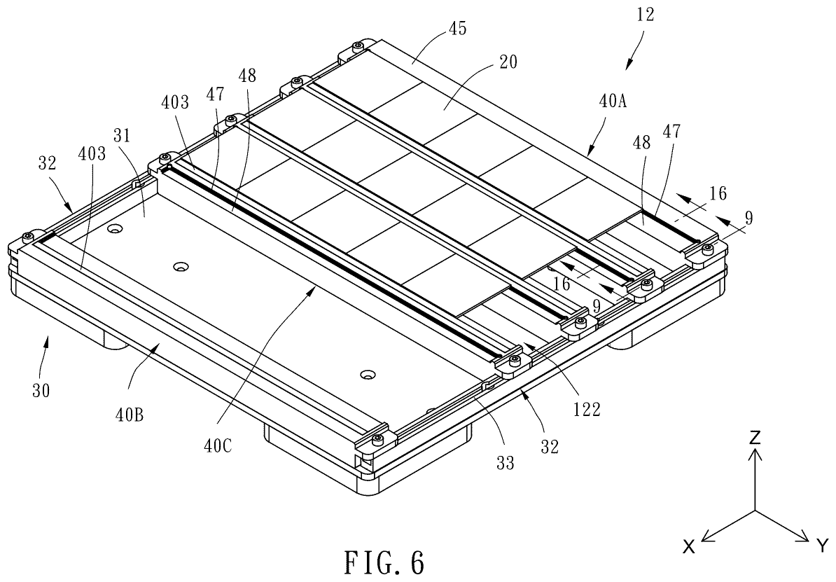

Referring to FIG. 4 to FIG. 6, the fixture device 12 in this embodiment includes a base 30, a positioning rod 40A, a positioning rod 40B, and three positioning rods 40C. Each of the positioning rods 40A, 40B only has one side adapted to clamp the substrate 20. However, two sides of each positioning rod 40C are both adapted to clamp the substrate 20. Their structures will be described in detail hereinafter. It can be seen in FIG. 6 that every two adjacent ones of the positioning rods 40A, 40B, 40C can clamp a substrate 20 or a plurality of substrates 20 arranged in a row along Y-axis. Therefore, as long as the fixture device of the present invention includes at least two positioning rods, it can achieve the substrate clamping function.

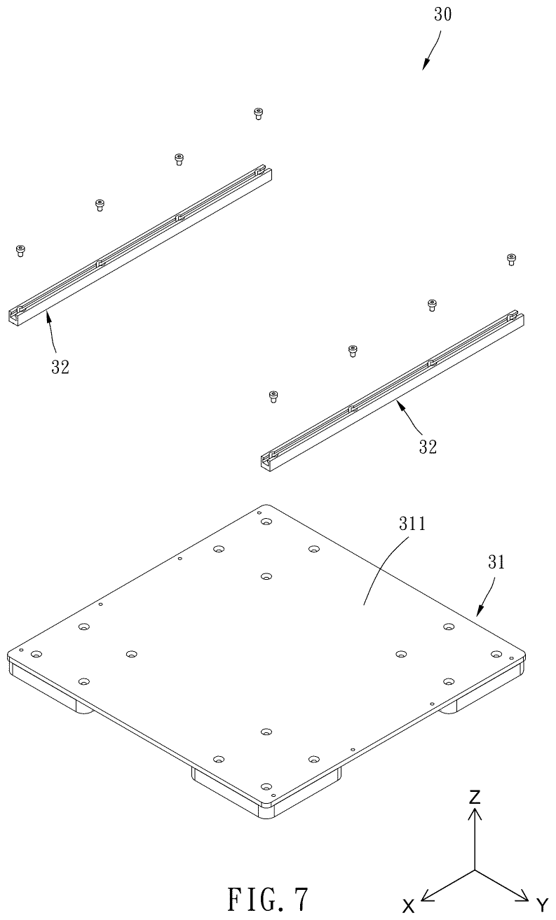

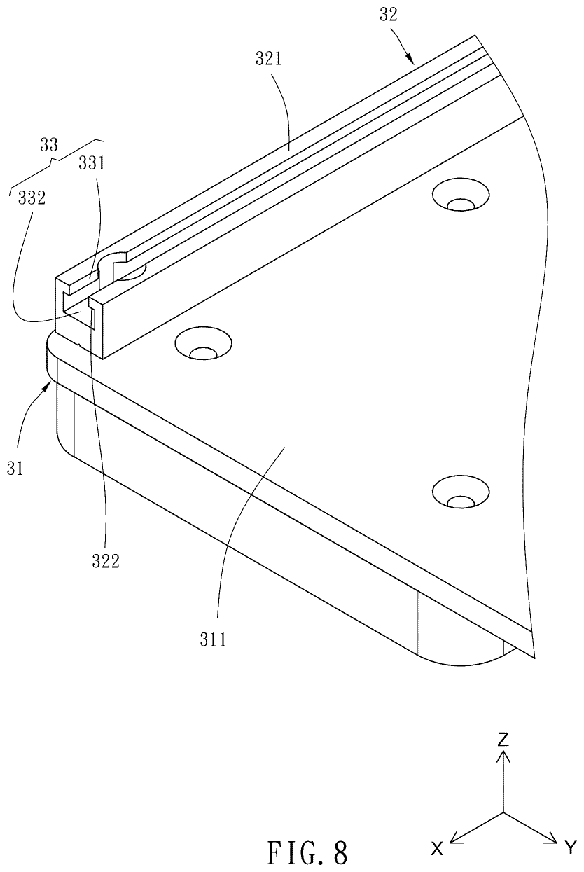

Referring to FIG. 7, the base 30 in this embodiment includes a main body 31 shaped as a rectangular board, and two width-axial guiding members 32 shaped as elongated rods. The main body 31 is defined with a length axis (Y-axis), a width axis (X-axis), and a height axis (Z-axis), which are perpendicular to each other. The width-axial guiding members 32 are disposed on two edges of the main body 31 respectively so as to extend along the width axis. Therefore, the width-axial guiding members 32 are spaced from each other for a distance for the positioning rods 40A, 40B, 40C to be disposed between the width-axial guiding members 32. As shown in FIG. 8, the width-axial guiding member 32 is a guide rail, which may be made of aluminum or other machinable materials by an extrusion forming process. The width-axial guiding member 32 includes a guiding groove 33 extending along the width axis. The guiding groove 33 includes a guiding portion 331 extending downward from the top surface 321 of the width-axial guiding member 32, and an accommodating portion 332 extending downward from the guiding portion 331, so that the guiding groove 33 is reverse T-shaped on Y-Z plane.

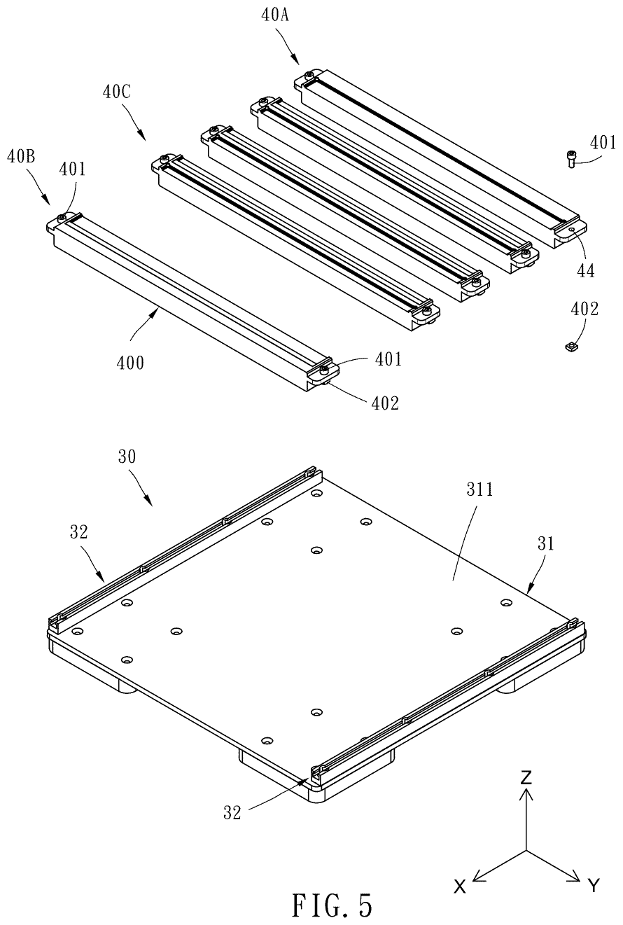

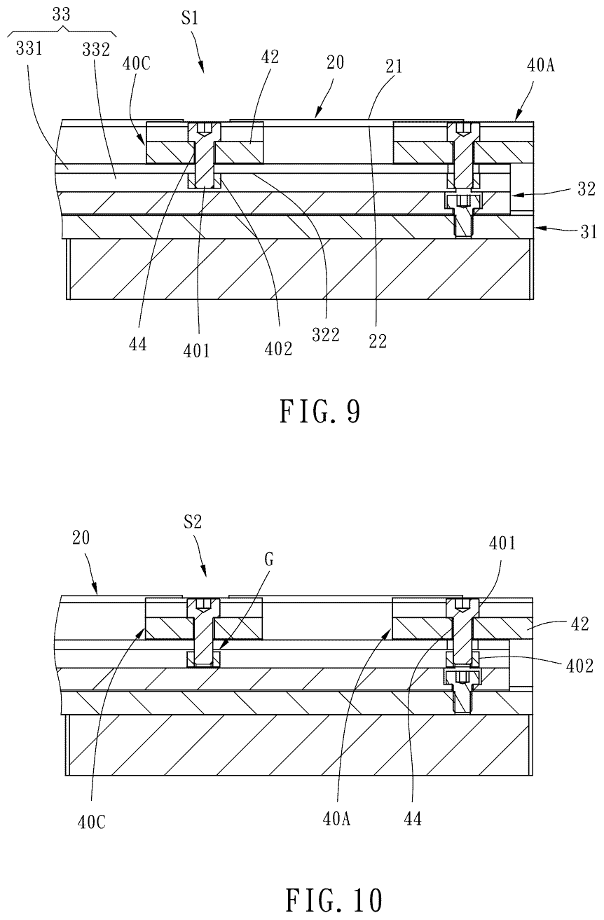

As shown in FIG. 4 and FIG. 5, each positioning rod 40A, 40B, 40C includes a main body 400, two bolts 401, and two nuts 402. The main body 400 includes a first end portion 41, a second end portion 42, and a body portion 43 extending into an elongated shape between the first end portion 41 and the second end portion 42. Each of the first end portion 41 and the second end portion 42 has a through hole 44. Each positioning rod 40A, 40B, 40C is disposed on the base 30 so as to extend along the length axis (Y-axis). The first end portion 41 and the second end portion 42 are disposed on the top surfaces 321 of the width-axial guiding members 32 respectively, and the body portion 43 is disposed on the upper surface 311 of the main body 31. The bolts 401 of each positioning rod 40A, 40B, 40C are inserted through the through holes 44 of the first end portion 41 and the second end portion 42 respectively, and inserted through the guiding portions 331 of the guiding grooves 33 of the width-axial guiding members 32 respectively. The nuts 402 of each positioning rod 40A, 40B, 40C are non-rotatably disposed in the accommodating portions 332 of the guiding grooves 33 of the width-axial guiding members 32 respectively, and screwed onto the bolts 401 respectively. For example, the nut 402 may be a square nut. As a result, each positioning rod 40A, 40B, 40C is changeable between a fixed state S1 (as shown in FIG. 9) and a slidable state S2 (as shown in FIG. 10). Taking the positioning rod 40C as an example for explanation, when the bolt 401 and the nut 402 provided at each of the first and second end portions 41, 42 of the positioning rod 40C are screwed tightly with each other, the nut 402 is pressed on an inner top surface 322 of the width-axial guiding member 32 (located between the guiding portion 331 and the accommodating portion 332 of the guiding groove 33), such that the positioning rod 40C is fixed to the width-axial guiding member 32, i.e. in the fixed state S1. When the bolt 401 and the nut 402 provided at each of the first and second end portions 41, 42 of the positioning rod 40C are not screwed tightly with each other, the nut 402 is spaced from the inner top surface 322 of the width-axial guiding member 32, and there is a gap G between the nut 402 and the inner top surface 322, such that the positioning rod 40C is in the slidable state S2 and slidable along the width axis (X-axis) by being guided by the guiding grooves 33 of the width-axial guiding members 32.

It should be mentioned here that the positioning rods 40A, 40B, 40C in this embodiment are all designed being changeable between the fixed state S1 and the slidable state S2. This kind of positioning rod is also referred to as slidable positioning rod in the present invention. However, the positioning rods included in the fixture device of the present invention may be configured such that only a part of them are slidable positioning rods, while the remaining positioning rods are fixed to the base 30 and non-slidable. For example, the positioning rod 40A in this embodiment can be modified to be non-slidable, and the positioning rods 40B, 40C remain as slidable positioning rods. As long as at least one of the two positioning rods for clamping a same substrate 20 or a same row of substrates 20 is the slidable positioning rod, the distance between the two positioning rods can be adjusted according to the width of the substrate 20 to be clamped. Moreover, as long as the fixture device 12 has at least three positioning rods, it can clamp substrates 20 of different sizes. For example, the positioning rod 40C shown in FIG. 9 and FIG. 10 can cooperate with the positioning rod 40A on the right side thereof to clamp a single substrate 20 or multiple substrates 20 arranged in a row along the length axis with any width, and the aforementioned positioning rod 40C can also cooperate with another positioning rod 40C (not shown in FIG. 9 and FIG. 10) on the left side thereof to clamp a single substrate 20 or multiple substrates 20 arranged in a row along the length axis with any width. The substrates 20 clamped on the left side and the right side of the aforementioned positioning rod 40C may have different widths. Therefore, IC substrates of different widths can be fixed on the fixture device 12 at the same time for testing.

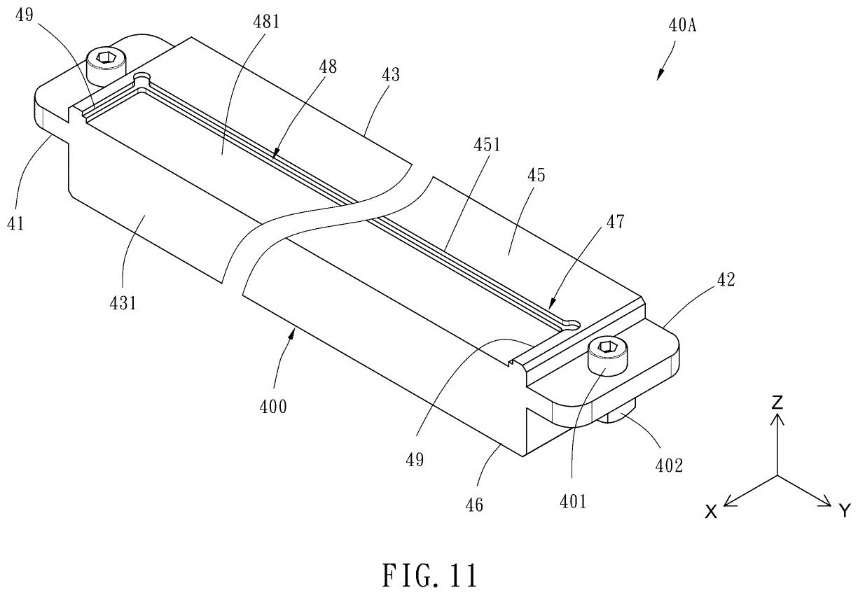

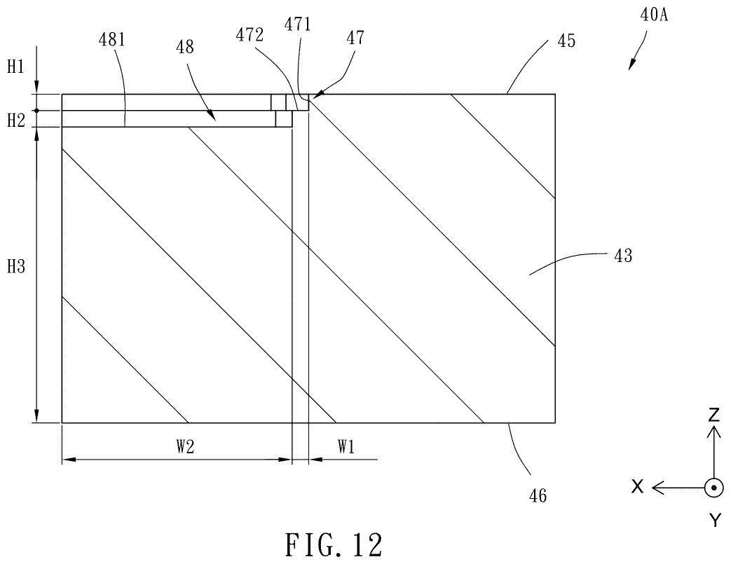

Referring to FIG. 11 and FIG. 12, the body portion 43 of the main body 400 of the positioning rod 40A includes a top surface 45 and a bottom surface 46, which respectively face toward two opposite directions of the height axis (i.e. the positive and negative directions of Z-axis) and each have long and short sides, and a main step 47 and a secondary step 48, which are formed downward in a step shape from the top surface 45. The bottom surface 46 is in contact with the upper surface 311 of the main body 31 of the base 30. The main step 47 is formed downward in a step shape from an edge 451 of the top surface 45 parallel to the length axis (Y-axis) (i.e. a long-side edge of the top surface 45), and the main step 47 further extends along the width axis (X-axis) to a side surface 431 of the body portion 43 so that the body portion 43 is further formed with two stopping portions 49 connected to the first and second end portions 41, 42 respectively. In this embodiment, the body portion 43 has a U-shaped configuration formed by the main step 47 and the two stopping portions 49. However, the present invention is unlimited thereto. For example, in addition to extending to the side surface 431 along the width axis (X-axis), the main step 47 may also extend along the length axis (Y-axis) to the first end portion 41 and the second end portion 42 so that the body portion 43 may have a straight-line-shaped main step 47 without any stopping portions 49. Secondly, the main step 47 includes a clamping surface 471 adjacent to the top surface 45, and a supporting surface 472 adjacent to the clamping surface 471. The secondary step 48 is formed downward into a step shape from the supporting surface 472 of the main step 47, and has a receiving surface 481 extending to the side surface 431 of the body portion 43. Both the supporting surface 472 of the main step 47 and the receiving surface 481 of the secondary step 48 face upward, i.e. face toward the positive direction of Z-axis, which corresponds to the direction facing the lower surface 22 of the substrate 20. On the height axis (Z-axis), the supporting surface 472 of the main step 47 is located between the top surface 45 of the positioning rod 40A and the receiving surface 481 of the secondary step 48, and the receiving surface 481 of the secondary step 48 is located between the supporting surface 472 of the main step 47 and the bottom surface 46 of the positioning rod 40A.

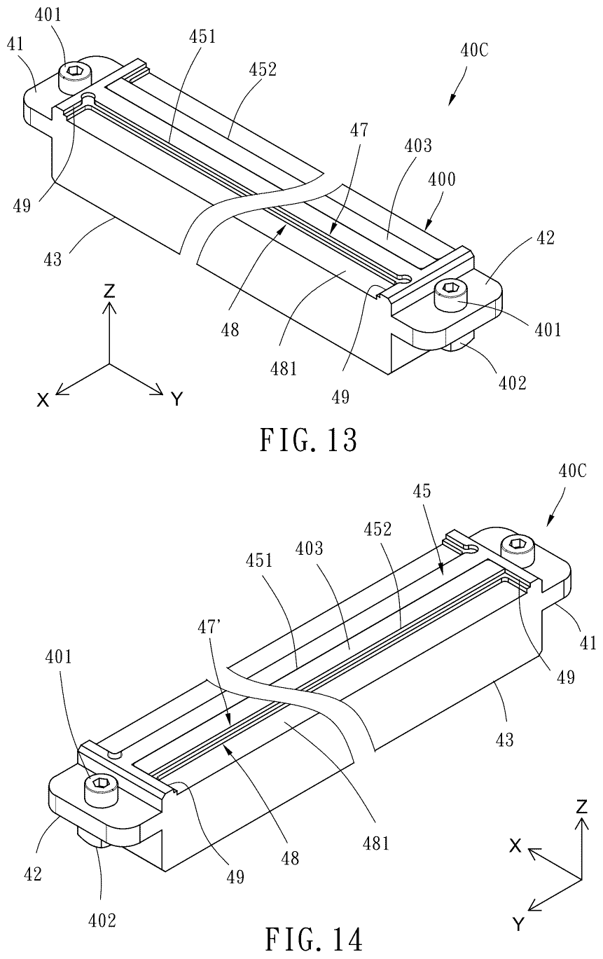

Referring to FIG. 13 to FIG. 15, the positioning rod 40C includes a top surface 45 and a bottom surface 46, which respectively face toward two opposite directions of the height axis (i.e. the positive and negative directions of Z-axis), two main steps 47, 47′ formed downward into a step shape from two opposite edges 451, 452 of the top surface 45 respectively, and two secondary steps 48 formed downward into a step shape from the main steps 47, 47′ respectively. The bottom surface 46 is in contact with the upper surface 311 of the main body 31 of the base 30. Each main step 47, 47′ includes a clamping surface 471 adjacent to the top surface 45, and a supporting surface 472 adjacent to the clamping surface 471. Each secondary step 48 is formed downward into a step shape from the supporting surface 472 of the main step 47, 47′, and has a receiving surface 481. Accordingly, the main steps 47, 47′ and the secondary steps 48 of the positioning rod 40C are similar to the main step 47 and the secondary step 48 of the positioning rod 40A. However, in addition to including the main body 400, the bolts 401, and the nuts 402, the positioning rod 40C further includes a cushioning strip 403 made of a resilient material (e.g. silicone or other elastically restorable materials). The cushioning strip 403 is embedded in the body portion 43 of the main body 400 so that the main body 400 and the cushioning strip 403 collectively form the top surface 45 of the positioning rod 40C. The clamping surface 471 and the supporting surface 472 of the main step 47 are portions of the main body 400. The supporting surface 472 of the main step 47′ is also a portion of the main body 400, but the clamping surface 471 of the main step 47′ is a portion of the cushioning strip 403. In other words, the clamping surface 471 of the main step 47′ is formed from the resilient material, and therefore has an effect of absorbing the manufacturing tolerances of the substrates, as described in detail below.

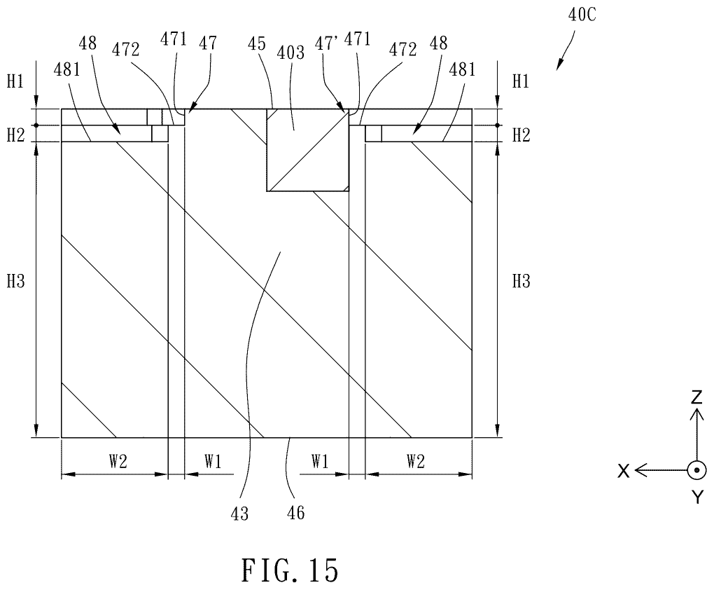

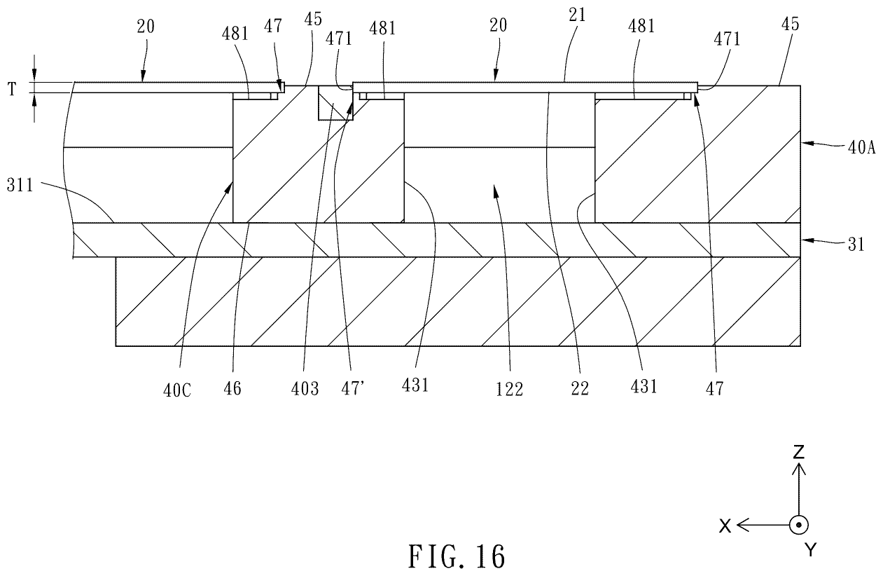

Referring to FIG. 12, FIG. 15, and FIG. 16, the clamping surface 471 of the main step 47 of the positioning rod 40A and the clamping surface 471 of the main step 47′ of the positioning rod 40C face each other. The positions of the positioning rods 40A, 40C fixed on the base 30 are set according to the width of the substrate 20 clamped by them, such that the substrate 20 is fixedly clamped by the clamping surface 471 of the main step 47 of the positioning rod 40A and the clamping surface 471 of the main step 47′ of the positioning rod 40C. At this time, the non-tested contact region 24 of the lower surface 22 of the substrate 20 (as shown in FIG. 3) is supported on the supporting surface 472 of the main step 47 of the positioning rod 40A and the supporting surface 472 of the main step 47′ of the positioning rod 40C. Additionally, the positioning rods 40A, 40C is provided therebetween with a gap 122 extending along the length axis (Y-axis) and located between the tested contact region 23 of the lower surface 22 of the substrate 20 (as shown in FIG. 3) and the base 30. That is, as shown in FIG. 16, the aforementioned gap 122 is formed between two opposite side surfaces 431 of the body portions 43 of the positioning rods 40A, 40C, the upper surface 311 of the main body 31 of the base 30, and an imaginary plane defined by the supporting surfaces 472 of the positioning rods 40A, 40C (this imaginary plane coincides with the lower surface 22 of the substrate 20). Further in detail, in the condition that there are the secondary steps 48, the gap 122 includes the space between the receiving surfaces 481 of the secondary steps 48 and the aforementioned imaginary plane. When the substrate 20 is supported on the supporting surface 472 of the main step 47 of the positioning rod 40A and the supporting surface 472 of the main step 47′ of the positioning rod 40C, this space corresponds to a part of the tested contact region 23 of the lower surface 22 of the substrate 20, so this part of the tested contact region 23 is prevented from direct contact with the receiving surfaces 481 of the secondary steps 48.

Although a batch of substrates 20 manufactured by a same manufacturing process have the same size, the substrates 20 of the same batch may still have manufacturing tolerances, thereby slightly different in width. Due to these manufacturing tolerances, when the substrates 20 of the same batch are placed on the main steps 47, 47′ of the positioning rods 40A, 40C, and the relative positions of the positioning rods 40A, 40C are adjusted adapting to the width of the substrates 20, some of the substrates 20 may still fail to abut against the clamping surfaces 471 of the main steps 47, 47′ if the clamping surfaces 471 of the main steps 47, 47′ are both non-elastic. In that case, when the fixture device 12 is being moved, or when the fixture device 12 has been placed onto the chuck 11 for testing of the substrates 20, the substrates 20 may slip out from between the positioning rods 40A, 40C and thereby will not be contacted by the probe tip 135 of the probe 132, thereby resulting in test failure. In the present invention, the resilient material is utilized to form at least a part of the clamping surfaces 471 so that at least one of the two clamping surfaces 471 clamping a same substrate 20 is formed from the resilient material. This allows the manufacturing tolerances of the substrates 20 to be absorbed, enabling the substrates 20 having slight dimensional differences due to manufacturing tolerances to be all securely clamped. Although the clamping surface 471 of the main step 47 on the left side of the positioning rod 40C shown in FIG. 16 is non-elastic, it cooperates with the resilient clamping surface 471 of the main step 47′ on the right side of another positioning rod 40C. When such two clamping surfaces 471 cooperatively clamp the substrates 20, the effect of absorbing manufacturing tolerances of the substrates can be still achieved.

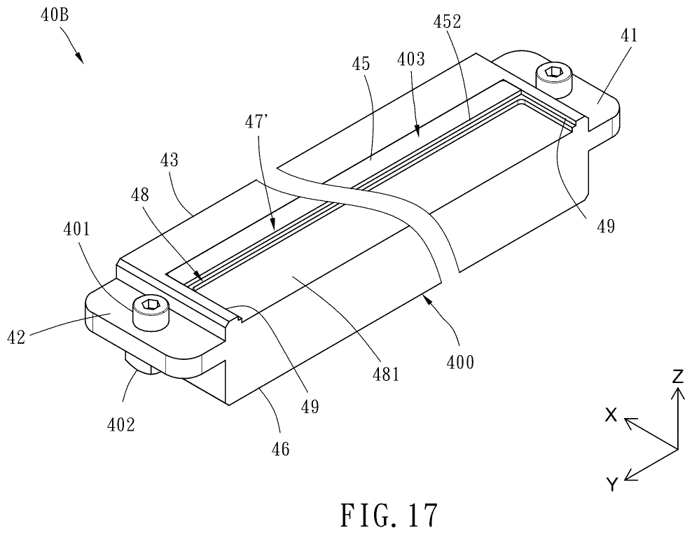

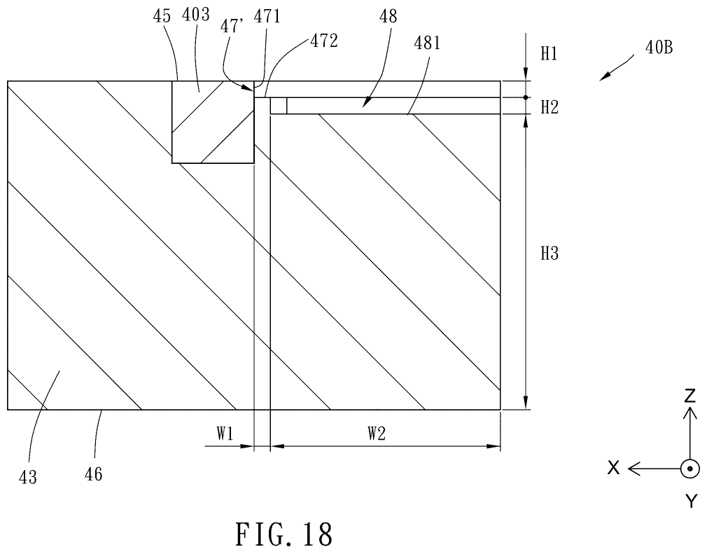

Referring to FIG. 17 and FIG. 18, the positioning rod 40B is similar to the positioning rod 40A. They both have only one side adapted to clamp the substrate. However, in addition to including the main body 400, the bolts 401 and the nuts 402, the positioning rod 40B further includes a cushioning strip 403 made of a resilient material. The cushioning strip 403 is embedded in the body portion 43 of the main body 400 so that the main body 400 and the cushioning strip 403 collectively form the top surface 45 of the positioning rod 40B. The positioning rod 40B has a main step 47′ formed downward into a step shape from the edge 452 formed from the cushioning strip 403, and a secondary step 48 formed downward into a step shape from the main step 47′. The main step 47′ includes a clamping surface 471 adjacent to the top surface 45, and a supporting surface 472 adjacent to the clamping surface 471. The secondary step 48 is formed downward into a step shape from the supporting surface 472 of the main step 47′, and has a receiving surface 481. In other words, the clamping surface 471 of the main step 47′ of the positioning rod 40B is formed from the resilient material, and has an effect of absorbing the manufacturing tolerances of the substrates, thereby adapted to cooperate with the non-elastic clamping surface 471 of the main step 47 of the positioning rod 40C to clamp the substrate 20.

From the foregoing description, it can be understood that the fixture device 12 of the present invention can clamp substrates 20 of different sizes by adjusting the distance between adjacent two of the positioning rods 40A, 40B, 40C, and the clamping surface 471 formed from the resilient material can absorb the manufacturing tolerances of the substrates 20. In addition, during testing of the substrate 20, the probe tip 135 of the probe 132 contacts the electrical contact on the upper surface 21 and presses on the substrate 20. At this time, the supporting surfaces 472 of the main step 47, 47′ of the positioning rods 40A, 40B, 40C support the substrate 20 at the non-tested contact region 24 of the lower surface 22, and there is a gap 122 between the tested contact region 23 of the lower surface 22 of the substrate 20 and the base 30. Therefore, the contacts on the lower surface 22 of the substrate 20 do not come into contact with the fixture device 12 or the base 30, thereby avoiding electrical interference. Moreover, the supporting surfaces 472 of the main steps 47, 47′ of the positioning rods 40A, 40B, 40C provide appropriate force to support the substrates 20 so that the substrates 20 do not come off the fixture device 12.

Since the supporting surfaces 472 of the main steps 47, 47′ of the positioning rods 40A, 40B, 40C can contact only the non-tested contact region 24 of the lower surface 22 of the substrate 20, the supporting surfaces 472 of the main steps 47, 47′ have very small widths. The substrate 20 may accidentally fall from the supporting surfaces 472 of the main steps 47, 47′. At this time, the receiving surfaces 481 of the secondary steps 48 receive the substrate 20, and prevent the substrate 20 from falling onto the base 30.

Further speaking, on the height axis (Z-axis), the top surface 45 of each positioning rod 40A, 40B, 40C and the supporting surface 472 of the main step 47, 47′ are defined therebetween with a first height H1, the supporting surface 472 of the main step 47, 47′ and the receiving surface 481 of the secondary step 48 are defined therebetween with a second height H2, and the receiving surface 481 of the secondary step 48 and the bottom surface 46 of the positioning rod 40A, 40B, 40C are defined therebetween with a third height H3. The preferred design is the third height H3 is larger than or equal to twice the sum of the first height HI and the second height H2, i.e. H3≥2(H1+H2). Such design makes the height position the receiving surface 481 of the secondary step 48 very close to that of the supporting surface 472, so that the falling height of the substrate 20 from the supporting surface 472 to the receiving surface 481 is very small. Consequently, when a testing operator places the substrate 20 back onto the supporting surface 472, the placement height is also very small. This reduces the risk that during the placement process, an adjacent substrate might be touched, and thereby the adjacent substrate might fall off as well. Additionally, on the width axis (X-axis), each main step 47, 47′ has a first width W1, and each secondary step 48 has a second width W2. The preferred design is the second width W2 is larger than or equal to three times the first width W1, i.e. W2≥3W1. Such design allows the secondary step 48 to effectively receive the substrate 20 falling from the main step 47, 47′, and prevent the substrate 20 from further falling from the secondary step 48.

In another aspect, during the testing, the probe device 13 and the chuck 11 are moved relative to each other on the height axis to approach each other to make the probe tip 135 of the probe 132 (as shown in FIG. 2) contact the electrical contact on the upper surface 21 of the substrate 20. In order to prevent the probe 132, during the testing, from firstly contacting the positioning rod and being interfered thereby to disable the probe tip 135 of the probe 132 from contacting the electrical contact on the upper surface 21 of the substrate 20 and thereby hindering proper testing and causing damage to the probe, the present invention further provide a preferred design aimed at this issue. That is, the first height H1 is preferred being smaller than or equal to the thickness T of the substrate 20 (as shown in FIG. 16). For example, by adopting the design of H1≤T, when the positioning rods 40A, 40C as shown in FIG. 16 clamp the substrate 20, the upper surface 21 of the substrate 20 is flush with or higher than the top surfaces 45 of the positioning rods 40A, 40C. In other words, the upper surface 21 of the substrate 20 does not lie below the top surfaces 45 of the positioning rods 40A, 40C. This can effectively prevent the aforementioned interference between the probe and the positioning rods. In addition, the probe tip 135 of the probe 132 and the bottom surface 136 of the probe seat 131 are defined therebetween along the height axis with a vertical distance D (as shown in FIG. 2). The first height H1 is preferred being smaller than half the vertical distance D. This can also effectively prevent the probe 132 from collision with the fixture device 12 or the substrate 20, thereby avoiding potential damage to the probe 132 or the substrate 20 resulted from such collision.

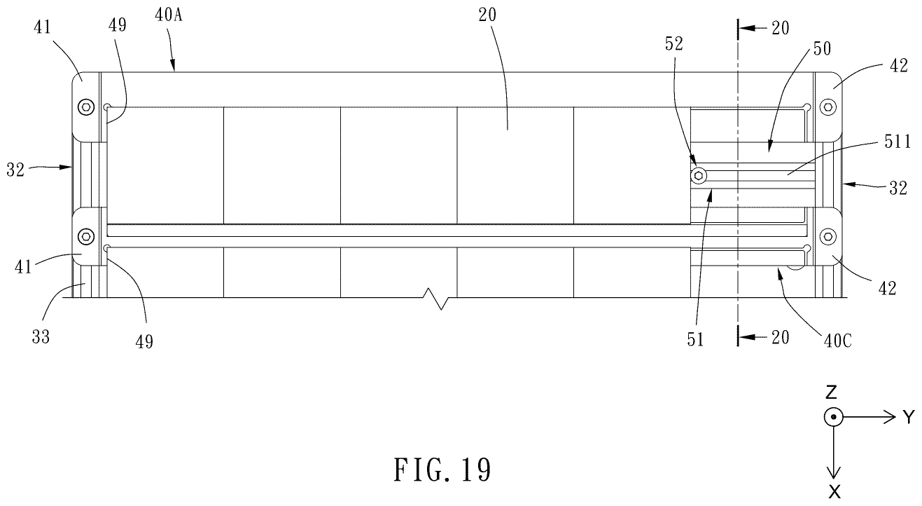

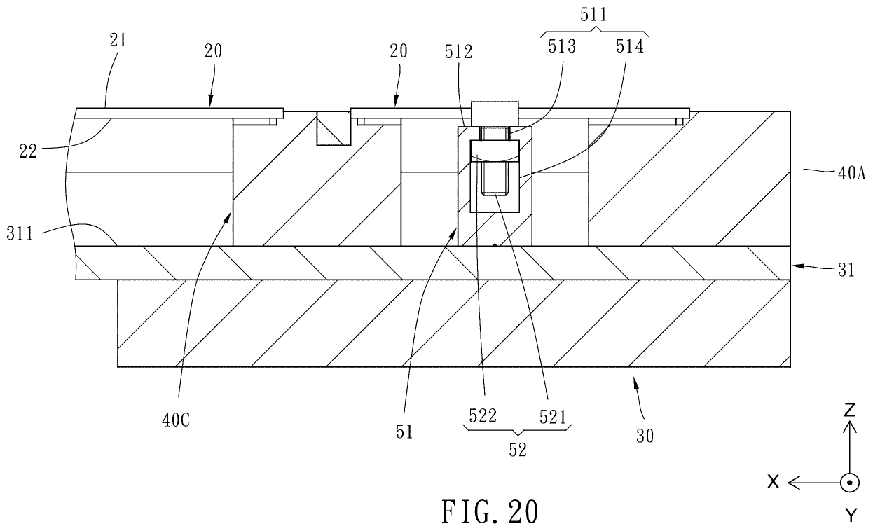

Referring to FIG. 19 and FIG. 20, a second preferred embodiment of the present invention is similar to the first preferred embodiment, but the fixture device in this embodiment further includes a length-axial positioning device 50. In this embodiment, the length-axial positioning device 50 is illustrated as being disposed between the positioning rod 40A and the adjacent positioning rod 40C. However, a length-axial positioning device 50 may likewise be disposed between other positioning rods.

The length-axial positioning device 50 in this embodiment includes a length-axial guiding member 51, and a length-axial positioning member 52. The length-axial guiding member 51 is similar to the above-described width-axial guiding member 32, but the length-axial guiding member 51 is fixed on the upper surface 311 of the base 30 so as to extend along the length axis (Y-axis). The length-axial guiding member 51 includes a guiding groove 511 extending along the length axis. The guiding groove 511 includes a guiding portion 513 extending downward from the top surface 512 of the length-axial guiding member 51, and an accommodating portion 514 extending downward from the guiding portion 513, so that the guiding groove 511 is reverse T-shaped on X-Z plane. The length-axial positioning member 52 includes a bolt 521, and a nut 522. The bolt 521 is inserted through the guiding portion 513 of the guiding groove 511. The nut 522 is disposed in the accommodating portion 514 of the guiding groove 511, and screwed onto the bolt 521. As a result, the bolt 521 and the nut 522 can be screwed tightly with each other and thereby fixed to the length-axial guiding member 51. When the bolt 521 and the nut 522 are not screwed tightly with each other, they can slide together along the guiding groove 511. In other words, the length-axial positioning member 52 is adjustable in position along the length axis by being guided by the length-axial guiding member 51, so as to abut against the substrate 20 between the first end portions 41 and the second end portions 42 of the positioning rods 40A, 40C.

Specifically speaking, when a single substrate 20 or multiple substrates 20 arranged in a row are placed on the main steps 47 and 47′ of the positioning rods 40A, 40C, the substrate 20 can be pushed toward the first end portions 41 of the positioning rods 40A, 40C, so that the single substrate 20 or the substrate 20 closest to the first end portions 41 among the multiple substrates 20 arranged in a row has its side facing toward the negative direction of Y-axis stopped by the stopping portions 49 connected to the first end portions 41. Conversely, the single substrate 20 or the substrate 20 farthest from the first end portions 41 among the multiple substrates 20 arranged in a row has its side facing toward the positive direction of Y-axis abutted by the length-axial positioning member 52. As a result, in addition to being clamped on the width axis by the clamping surfaces 471 of the main steps 47, 47′ of the positioning rods 40A, 40C, the single substrate 20 or multiple substrates 20 arranged in a row are further clamped on the length axis by the stopping portions 49 of the positioning rods 40A, 40C and the length-axial positioning member 52. This makes the substrate 20 fixed more securely on the fixture device 12, preventing the substrate 20 from moving along the length axis. If the substrate 20 may still slightly slide along the length axis when the fixture device 12 is moved or when the fixture device 12 is placed on the chuck 11 for testing, such sliding may cause the substrate 20 to fail to be contacted by the probe tip 135 of the probe 132, resulting in a failed test result. Therefore, the present invention uses the length-axial positioning member 52 to cooperate with the stopping portions 49 of the positioning rods to secure the substrate 20 on the length axis, thereby preventing the substrate from sliding.

The length-axial positioning member in the present invention is unlimited to that provided in this embodiment. For example, the length-axial positioning member may be a magnet. In this case, the main body 31 of the base 30 may be made of a magnetic material, such as iron, so that the magnet can be fixedly attracted to the main body 31 of the base 30. In addition, the width-axial guiding member 32 of the base 30 in the present invention is unlimited to such guide rail as described in the first preferred embodiment. For example, each of the width-axial guiding members 32 may be a guide rod, and the first end portion 41 and the second end portion 42 of the slidable positioning rod have structures that can be sleeved onto the guide rods and can be fixedly clamped onto the guide rods. That is, the first end portion 41 and the second end portion 42 are provided therethrough along the width axis with through holes for being sleeved onto the guide rods. Moreover, the first end portion 41 and the second end portion 42 are each provided with a clamping member capable of clamping toward the through hole or reversely releasing the clamping. For example, the clamping member may be configured as a spool clamp, a pneumatic clamp, an elastic clamp, and so on. When the clamping members located at the first end portion 41 and the second end portion 42 are released, the clamping members loosen their clamping effect between the first and second end portions 41, 42 and the guide rods. At this time, the positioning rod is in a slidable state, thereby adjustable in position to adapt to the width of the substrate 20. After the adjustment is completed, the clamping effect of the clamping members are activated again to place the positioning rod in the fixed state.

At last, it should be mentioned again that the constituent elements disclosed in the above embodiments of the present invention are only taken as examples for illustration, not intended to limit the scope of the present invention. The substitution or variation of other equivalent elements should be included within the scope of the claims of the present invention.

What is claimed is:

1. A fixture device for integrated circuit substrate testing, which is adapted to clamp a substrate, the substrate comprising an upper surface and a lower surface, the lower surface comprising a tested contact region and a non-tested contact region, the fixture device comprising:
a base defined with a length axis, a width axis, and a height axis, which are perpendicular to each other; and
two positioning rods, each of the positioning rods being disposed on the base so as to extend along the length axis, at least one of the two positioning rods being a slidable positioning rod, the slidable positioning rod being changeable between a slidable state and a fixed state, the slidable positioning rod in the slidable state being slidable relative to the base along the width axis for adapting to a width of the substrate, the slidable positioning rod in the fixed state being fixed to the base so that the substrate is fixedly clamped by the two positioning rods;
wherein each of the positioning rods comprises a top surface and a bottom surface, which face toward two opposite directions of the height axis respectively, and a main step formed downward into a step shape from an edge of the top surface; the main step comprises a clamping surface adjacent to the top surface, and a supporting surface adjacent to the clamping surface; the clamping surfaces of the main steps of the two positioning rods face each other, and at least one of the clamping surfaces is formed from an resilient material, such that the two positioning rods are arranged in a way that the clamping surfaces of the main steps of the two positioning rods are adapted to cooperatively clamp the substrate, the supporting surfaces of the main steps of the two positioning rods are adapted to cooperatively support the non-tested contact region of the lower surface of the substrate, and the two positioning rods are provided therebetween with a gap extending along the length axis and located between the tested contact region of the lower surface of the substrate and the base.

2. The fixture device for integrated circuit substrate testing as claimed in claim 1, wherein each of the positioning rods further comprises a secondary step formed downward into a step shape from the supporting surface of the main step; the secondary step comprises a receiving surface facing upward; on the height axis, the supporting surface of the main step is located between the top surface of the positioning rod and the receiving surface of the secondary step, the receiving surface of the secondary step is located between the supporting surface of the main step and the bottom surface of the positioning rod, the top surface of the positioning rod and the supporting surface of the main step are defined therebetween with a first height, the supporting surface of the main step and the receiving surface of the secondary step are defined therebetween with a second height, and the receiving surface of the secondary step and the bottom surface of the positioning rod are defined therebetween with a third height; the third height is larger than or equal to twice a sum of the first height and the second height.

3. The fixture device for integrated circuit substrate testing as claimed in claim 2, wherein on the width axis, the main step has a first width, and the secondary step has a second width; the second width is larger than or equal to three times the first width.

4. The fixture device for integrated circuit substrate testing as claimed in claim 2, wherein the first height is smaller than or equal to a thickness of the substrate.

5. The fixture device for integrated circuit substrate testing as claimed in claim 1, wherein the base comprises a main body, and two width-axial guiding members; the two width-axial guiding members are spaced from each other for a distance, and disposed on the main body so as to extend along the width axis; the slidable positioning rod comprises a first end portion, and a second end portion; the first end portion and the second end portion are disposed on the two width-axial guiding members respectively; in the slidable state, the slidable positioning rod slides along the width axis by being guided by the two width-axial guiding members.

6. The fixture device for integrated circuit substrate testing as claimed in claim 5, wherein each of the width-axial guiding members comprises a guiding groove extending along the width axis; the guiding groove comprises a guiding portion, and an accommodating portion; each of the first end portion and the second end portion of the slidable positioning rod has a through hole; each of the first end portion and the second end portion is provided with a bolt inserted through the through hole, and a nut screwed onto the bolt; the bolt is inserted through the guiding portion of the guiding groove; the nut is disposed in the accommodating portion of the guiding groove, and able to be screwed tightly on the bolt to fasten the slidable positioning rod to the width-axial guiding member.

7. The fixture device for integrated circuit substrate testing as claimed in claim 1, wherein when the substrate is fixedly clamped by the two positioning rods, the upper surface of the substrate is flush with or higher than the top surfaces of the two positioning rods.

8. The fixture device for integrated circuit substrate testing as claimed in claim 1, wherein each of the positioning rods comprises a first end portion, a second end portion, and a stopping portion connected with the first end portion for the substrate to be stopped by the stopping portions of the two positioning rods; the fixture device further comprises a length-axial positioning member disposed between the two positioning rods; the length-axial positioning member is adjustable in position along the length axis for contacting the substrate between the first end portions and the second end portions of the two positioning rods.

9. The fixture device for integrated circuit substrate testing as claimed in claim 8, wherein the fixture device further comprises a length-axial guiding member disposed between the two positioning rods; the length-axial guiding member comprises a guiding groove extending along the length axis; the guiding groove comprises a guiding portion, and an accommodating portion; the length-axial positioning member comprises a bolt, and a nut screwed onto the bolt; the bolt is inserted through the guiding portion of the guiding groove; the nut is disposed in the accommodating portion of the guiding groove, and able to be screwed tightly on the bolt, thereby fastened to the length-axial guiding member.

10. The fixture device for integrated circuit substrate testing as claimed in claim 1, wherein at least one of the two positioning rods further comprises another said main step formed downward into a step shape from another edge of the top surface; at least one of the clamping surfaces of the two main steps included in the same positioning rod is formed from said resilient material.

11. A testing system for integrated circuit substrate testing, which is adapted for testing a substrate, the testing system comprising:
a chuck;
a fixture device as claimed in claim 1, which is disposed on the chuck for clamping the substrate; and
a probe device comprising a probe seat, and a probe disposed on the probe seat for testing the substrate clamped by the fixture device.

12. The testing system for integrated circuit substrate testing as claimed in claim 11, wherein each of the positioning rods of the fixture device further comprises a secondary step formed downward into a step shape from the supporting surface of the main step; the secondary step comprises a receiving surface facing upward; on the height axis, the supporting surface of the main step is located between the top surface of the positioning rod and the receiving surface of the secondary step; for each of the positioning rods, a height defined between the top surface thereof and the supporting surface of the main step thereof along the height axis is smaller than or equal to a thickness of the substrate.

13. The testing system for integrated circuit substrate testing as claimed in claim 11, wherein a probe tip of the probe and a bottom surface of the probe seat are defined therebetween with a vertical distance along the height axis; for each of the positioning rods, a height defined between the top surface thereof and the supporting surface of the main step thereof along the height axis is smaller than half the vertical distance.

14. A positioning rod for integrated circuit substrate testing, the positioning rod being defined with a length axis, a width axis, and a height axis, which are perpendicular to each other, the positioning rod extending into an elongated shape along the length axis, the positioning rod comprising a top surface and a bottom surface, which face toward two opposite directions of the height axis respectively, and two main steps formed downward into a step shape from two opposite edges of the top surface respectively, each of the main steps comprising a clamping surface adjacent to the top surface, and a supporting surface adjacent to the clamping surface, the clamping surface of each of the main steps being adapted to cooperate with another positioning rod to clamp a substrate, at least one of the clamping surfaces of the two main steps being formed from an resilient material.

15. The positioning rod for integrated circuit substrate testing as claimed in claim 14, wherein the positioning rod further comprises two secondary steps formed downward into a step shape from the supporting surfaces of the two main steps respectively; each of the secondary steps comprises a receiving surface facing upward; on the height axis, the supporting surface of each of the main steps is located between the top surface of the positioning rod and the receiving surface of each of the secondary steps, the receiving surface of each of the secondary steps is located between the supporting surface of each of the main steps and the bottom surface of the positioning rod, the top surface of the positioning rod and the supporting surface of each of the main steps are defined therebetween with a first height, the supporting surface of each of the main steps and the receiving surface of each of the secondary steps are defined therebetween with a second height, and the receiving surface of each of the secondary steps and the bottom surface of the positioning rod are defined therebetween with a third height; the third height is larger than or equal to twice a sum of the first height and the second height.

16. The positioning rod for integrated circuit substrate testing as claimed in claim 15, wherein on the width axis, each of the main steps has a first width, and each of the secondary steps has a second width; the second width is larger than or equal to three times the first width.

17. The positioning rod for integrated circuit substrate testing as claimed in claim 15, wherein the first height is smaller than or equal to a thickness of the substrate.
